(19) United States
(12) Patent Application Publication
(10) Pub. No.: US 2025/0022654 A1
(43) Pub. Date: Jan. 16, 2025

(54) VOLTAGE-ISOLATED INTEGRATED CIRCUIT PACKAGES WITH PIN-COUPLED COILS

(71) Applicant: Allegro MicroSystems, LLC, Manchester, NH (US)

(72) Inventors: Vijay Mangtani, Nashua, NH (US); William P. Taylor, Amherst, NH (US)

(73) Assignee: Allegro MicroSystems, LLC, Manchester, NH (US)

(21) Appl. No.: 18/349,266

(22) Filed: Jul. 10, 2023

(51) Int. Cl. H01F 41/04; H01F 17/00; H01F 41/02

(52) U.S. Cl. CPC H01F 41/046; H01F 17/0006; H01F 41/0246; H01L 28/10; H01F 2017/0086

(57) ABSTRACT

Aspects of the present disclosure include systems, structures, circuits, and methods providing pin-coupled transformers and/or pin-coupled coil structures. A pin-coupled coil structure can include first and second substrates, each having a plurality of conductive traces. The conductive traces of the substrates are connected by conductive pins, forming one or more pin-coupled coil structures. Two pin-coupled coils structure can be configured around a transformer core forming a pin-coupled transformer structure. The pin-coupled transformer structure can be included in integrated circuit (chip) packages or modules. The packages and modules may include various types of circuits; in some examples, chip packages or modules may include a galvanically isolated gate driver or other high voltage circuit.

### BACKGROUND

Solid state switches typically include a transistor structure. The controlling electrode of the switch, usually referred to as its gate (or base), is typically controlled (driven) by a switch drive circuit, sometimes also referred to as gate drive circuit. Such solid state switches are typically voltage-controlled, turning on when the gate voltage exceeds a manufacturer-specific threshold voltage by a margin, and turning off when the gate voltage remains below the threshold voltage by a margin.

Switch drive circuits typically receive their control instructions from a controller such as a pulse-width-modulated (PWM) controller via one or more switch driver inputs. Switch drive circuits deliver their drive signals directly (or indirectly via networks of active and passive components) to the respective terminals of the switch (gate and source).

Some electronic systems, including ones with solid state switches, have employed galvanic isolation to prevent undesirable DC currents flowing from one side of an isolation barrier to the other. Such galvanic isolation can be used to separate circuits in order to protect users from coming into direct contact with hazardous voltages.

Various transmission techniques are available for signals to be sent across galvanic isolation barriers including optical, capacitive, and magnetic coupling techniques. Magnetic coupling typically relies on use of a transformer to magnetically couple circuits on the different sides of the transformer, typically referred to as the primary and secondary sides, while also providing galvanic separation of the circuits.

Transformers used for magnetic-coupling isolation barriers typically utilize a magnetic core to provide a magnetic path to channel flux created by the currents flowing in the primary and secondary sides of the transformer. Magnetic-coupling isolation barriers have been shown to have various drawbacks, including manufacturing problems, for integrated circuit (IC) packages due to the included magnetic core.

### SUMMARY

An aspect of the present disclosure includes chip packages for galvanically isolated integrated circuits (ICs) with transformer including pin-coupled coil structures.

One general aspect includes a pin-coupled transformer structure. The pin-coupled transformer structure can include: a first substrate having a first plurality of conductive traces; a second substrate having a second plurality of conductive traces, a soft ferromagnetic core configured as a closed loop and disposed between the first and second substrates, and a plurality of conductive pins disposed between and connecting the first plurality of conductive traces to the second plurality of conductive traces, where the first and second pluralities of conductive traces and the plurality of conductive pins may include first and second pin-coupled coil structures and can be configured about the soft ferromagnetic core as first and second transformer coils. In some embodiments, a transformer with pin-coupled coil structures may have, e.g., a step up, a step down, or a power transformer configuration.

Implementations may include one or more of the following features. The transformer structure can include first and second pin-coupled coil structures that are galvanically separated. The first and/or second substrate may include a printed circuit board (PCB). The first and/or second substrate may include a lead frame. The first and/or second substrate may include a molded lead frame. The first and/or second substrate may include a glass substrate including a plurality of thin glass layers. The first and/or second substrate may include a ceramic substrate. The ceramic substrate may include high-temperature cofired ceramic (HTCC). The ceramic substrate may include low-temperature cofired ceramic (LTCC). The transformer structure may include an IC die connected to the first pin-coupled coil structure. The IC die connected to the first pin-coupled coil structure may include an integrated circuit. The transformer structure may include an IC die connected to the second pin-coupled coil structure. The IC die connected to the second pin-coupled coil structure may include an integrated circuit. The integrated circuit may include a gate driver circuit. The first pin-coupled coil structure may include a primary side of the transformer structure. The second pin-coupled coil structure may include a secondary side of the transformer structure. The transformer structure may include a dielectric material disposed between the first and second pin-coupled coil structures. The transformer structure may include a dielectric tape material disposed about the soft ferromagnetic core to facilitate isolation between the soft ferromagnetic core and the first and second substrates. The molding material may be configured as a package body.

One general aspect includes a method of making a pin-coupled transformer structure. The method can include: providing a first substrate having a first plurality of conductive traces; providing a second substrate having a second plurality of conductive traces; providing a soft ferromagnetic core configured as a closed loop and disposed between the first and second substrates; and connecting a plurality of conductive pins to the first plurality of conductive traces and to the second plurality of conductive traces, where the first and second pluralities of conductive traces and the plurality of conductive pins may include first and second pin-coupled coil structures and are configured about the soft ferromagnetic core as first and second transformer coils. In some embodiments, a transformer made by the method and having pin-coupled coil structures may have, e.g., a step up, a step down, or a power transformer configuration.

Implementations may include one or more of the following features. The first and second pin-coupled coil structures may be galvanically separated. The first and/or second substrate may include a printed circuit board (PCB). The first and/or second substrate may include a molded lead frame. The first and/or second substrate may include a glass substrate including a plurality of thin glass layers. The first and/or second substrate may include a ceramic substrate. The ceramic substrate may include high-temperature cofired ceramic (HTCC). The ceramic substrate may include low-temperature cofired ceramic (LTCC). The method may include providing a semiconductor die disposed on the first and/or second substrate. The method where the semiconductor die may include an integrated circuit. The semiconductor die may be disposed on a high-voltage side of the transformer structure and the integrated circuit may include a gate driver circuit. The molding material may be configured as a package body.

The features and advantages described herein are not all-inclusive; many additional features and advantages will be apparent to one of ordinary skill in the art in view of the drawings, specification, and claims. Moreover, it should be noted that the language used in the specification has been selected principally for readability and instructional purposes, and not to limit in any way the scope of the present disclosure, which is susceptible of many embodiments. What follows is illustrative, but not exhaustive, of the scope of the present disclosure.

### BRIEF DESCRIPTION OF THE DRAWINGS

The manner and process of making and using the disclosed embodiments may be appreciated by reference to the figures of the accompanying drawings. In the figures like reference characters refer to like components, parts, elements, or steps/actions; however, similar components, parts, elements, and steps/actions may be referenced by different reference characters in different figures. It should be appreciated that the components and structures illustrated in the figures are not necessarily to scale, emphasis instead being placed upon illustrating the principals of the concepts described herein. Furthermore, embodiments are illustrated by way of example and not limitation in the figures, in which:

FIG. 1 is a diagram showing a side view of an example pin-coupled coil structure, in accordance with the present disclosure;

FIG. 2 is a diagram showing a top view of an example pin-coupled transformer structure, in accordance with the present disclosure;

FIG. 3 is a diagram showing a side view of an alternate example pin-coupled coil structure, in accordance with the present disclosure;

FIG. 4 is a diagram showing a top view of an alternate example pin-connection structure, in accordance with the present disclosure;

FIG. 5 is a box diagram showing an example method of fabricating a pin-coupled transformer structure for an IC package, in accordance with the present disclosure; and

FIG. 6 is a diagram showing a side view of an example voltage-isolated IC package with pin-coupled transformer structure, in accordance with the present disclosure.

### DETAILED DESCRIPTION

The features and advantages described herein are not all-inclusive; many additional features and advantages will be apparent to one of ordinary skill in the art in view of the drawings, specification, and claims. Moreover, it should be noted that the language used in the specification has been selected principally for readability and instructional purposes, and not to limit in any way the scope of the inventive subject matter. The subject technology is susceptible of many embodiments. What follows is illustrative, but not exhaustive, of the scope of the subject technology.

Aspects of the present disclosure are directed to and include systems, structures, circuits, and methods providing transformers and transformer structures that can be used for galvanic isolation (a.k.a., voltage isolation). Some embodiments and examples can include pin-coupled coil structures used with a core in a transformer configuration. In some embodiments, a transformer with pin-coupled coil structures may have, e.g., a step up, a step down, or a power transformer configuration. Some embodiments and examples can include integrated circuit (IC) packages or modules with pin-coupled transformer structures.

The IC packages and modules may include various types of circuits; in some examples, IC packages or modules may include a galvanically isolated gate driver or other high voltage circuit, etc. First and second semiconductor die having one or more integrated circuits (a.k.a., “IC die”) can be included in the packages. Such integrated circuits can include, e.g., but are not limited to, high-voltage circuits such as galvanically-isolated gate drivers configured to drive an external gate on a solid-state switch, e.g., a MOSFET, GaNFET, SiCFET, an IGBT, or another load.

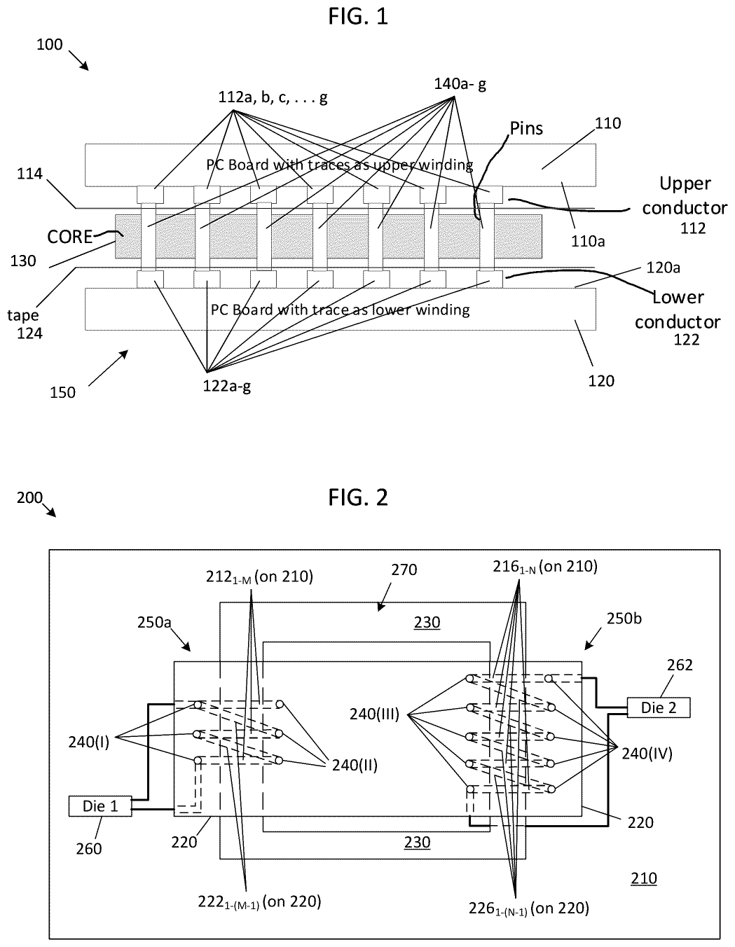

FIG. 1 is a diagram showing a side view of an example pin-coupled coil structure 100, in accordance with the present disclosure. Structure 100 can include first and second electrical substrates 110, 120, e.g., printed circuit boards (PCBs), as shown. Substrates 110, 120 can include conductive traces 112a-g, 122a-g, respectively, on surfaces 110a, 120a facing one another, as shown. The number of conductive traces of/on each substrate 110, 120 may vary in other embodiments and examples. A core, e.g., of soft ferromagnetic material, 130 can be disposed between substrates 110 and 120. A plurality of conductive pins 140a-g (e.g., columns, cylinders, plugs, etc.) can connect traces 112a-g and 122a-g; another plurality (set) of conductive pins (not shown) is present behind the structure shown (including core 130). The sets of pins and conductive traces 112a-g, traces 122a-g form a pin-coupled coil structure 150 having a plurality of windings (conductive paths) disposed (configured) about core 130. The number of conductive pins may vary in other embodiments and examples. To facilitate isolation of core 130 from other structure(s), insulating material 114, 124, e.g., tape, may (optionally) be disposed on conductive traces 112a-g, 122a-g and/or substrates 110, 120, respectively, as shown. As described below, in some embodiments, pin-coupled coil structure 150 can be used as a transformer coil in conjunction with another coil (with either similar or different structure) for a transformer or transformer structure.

FIG. 2 is a diagram showing a top view of an example pin-coupled transformer structure 200, in accordance with the present disclosure. Structure 200 includes a first substrate (e.g., PCB) 210 and a second substrate 220. Structure 200 can include a core 230, which may include soft ferromagnetic material, e.g., ferrite, a nickel alloy, or SiFe, and may have a closed shape, e.g., toroidal or rectangular, as shown. Core 230 is shown disposed between substrates 210 and 220. In some embodiments and examples, either of substrates 210 or 220 may be replaced with two or more substrates.

Substrate 210 can include a plurality (e.g., one or more sets) of conductive traces on/in a surface, e.g., as indicated by first trace set 212_{1-M} (having M separate traces on surface of substrate 210) and second trace set 216_{1-N} (having N separate traces on surface of substrate 210). As shown, first trace set 212_{1-M} and second trace set 216_{1-N} may have different numbers of conductive traces, respectively; in other embodiments, first trace set 212_{1-M} and second trace set 216_{1-N} may have the same number of conductive traces. Similarly, substrate 220 can include a plurality (e.g., one or more sets) of conductive traces on/in a surface, e.g., as indicated by first trace set 222_{1-(M-1)} (having M−1 separate traces on side of substrate 220 facing substrate 210) and second trace set 226_{1-(N-1)} (having N−1 separate traces on side of substrate 220 facing substrate 210). As shown, first trace set 222_{1-(M-1)} and second trace set 226_{1-(N-1)} may have different numbers of conductive traces, respectively, in some embodiments; in other embodiments, first trace set 222_{1-(M-1)} and second trace set 226_{1-(N-1)} may have the same number of conductive traces. While the trace sets on second substrate 220 are shown as having fewer traces than the corresponding trace sets (used for the respective pin-coupled coil structure) on first substrate 210, in other embodiments one or both trace sets on second substrate 220 may have a greater or equal number of traces as the corresponding trace set on first substrate 210.

The pluralities of traces of each substrate 210, 220 can be coupled, respectively, by a plurality (one or more sets) of pins or pin-like (columnar or rod-like) conductive structures, indicated as pin sets 240(I)-(IV), to form first and second pin-coupled coil structures 250a-b (e.g., each similar to pin-coupled coil structure 150 of FIG. 1).

Two groups (sets) of pins 240(I)-(II) are shown at a first area or region of core 230 (left side of figure), connecting conductive traces 212_{1-M} of substrate 210 to conductive traces 222_{1-(M-1)} of substrate 220; those pins and traces can form a first pin-coupled coil structure 250a. Similarly, two separate groups (sets) of pins 240(III)-(IV) are shown at a second region of core 230 (right side of figure), connecting conductive traces 216_{1-N} on substrate 210 to conductive traces 226_{1-(N-1)} on substrate 220; those pins and traces can form a second pin-coupled coil structure 250b. First pin-coupled coil structure 250a and second pin-coupled coil structure 250b can operate with core 230 as a transformer 270. As shown, pin-coupled coil structures 250a and 250b can be connected to first and second IC die 260, 262, respectively, e.g., for magnetic coupling and galvanic isolation of die 260, 262. The die 260, 262 may have other and/or additional connections to the PCB or package leads than what is shown in FIG. 2. These other/additional connections may be for power, voltage reference, current, communications or other electrical connections between the die and the PCB or package leads.

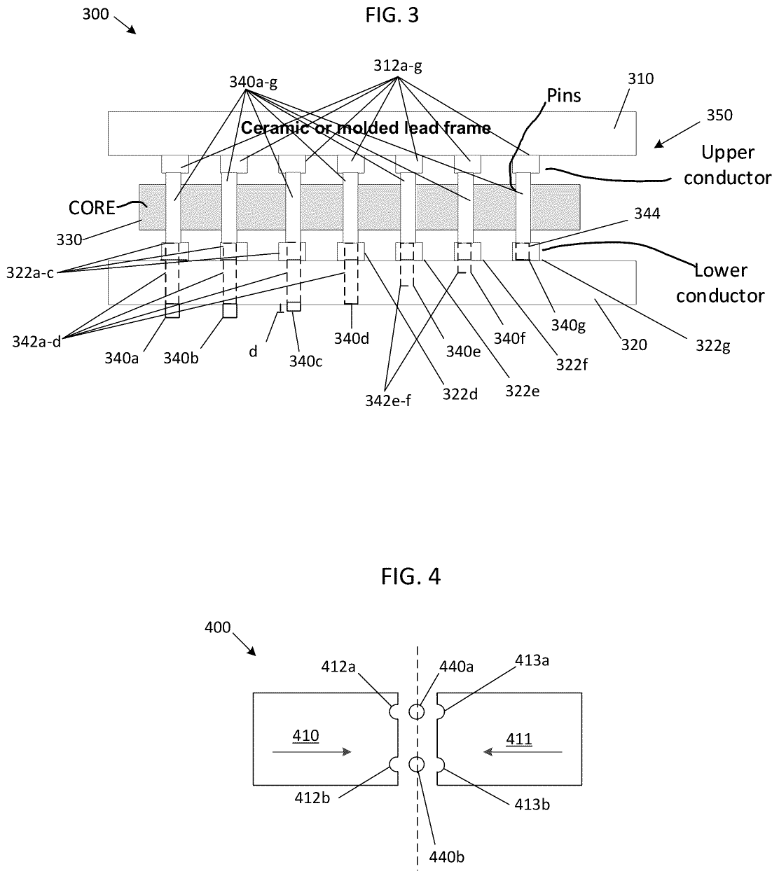

FIG. 3 is a diagram showing a side view of an alternate example pin-coupled coil structure 300, in accordance with the present disclosure. Structure 300 can include first and second substrates 310, 320, e.g., ceramic substrates, PCBs, or molded lead frames, etc. Transformer (magnetic) core 330 is shown disposed between substrates 310 and 320. Core 330 can be made of or include soft ferromagnetic material. A first plurality of conductive traces 312a-g is shown disposed on a surface of substrate 310 while a second plurality of conductive traces 322a-g is shown disposed on a surface of substrate 320. A plurality (set) of conductive pins 340a-g is shown connecting traces 312a-g to traces 322a-g; another plurality (set) of conductive pins (not shown) is present behind the structure shown (including core 330). The sets of pins and conductive traces 312a-g, traces 322a-g form a pin-coupled coil structure 350 having a plurality of windings (conductive paths) disposed (configured) about core 330. In some embodiments, pin-coupled coil structure 350 can be used with another coil (with either similar or different structure) for a transformer or transformer structure.

In some embodiments and examples, pins 340a-g may be connected/coupled to conductive traces (e.g., conductive areas or regions) 322a-g on a substrate 320 by holes, as shown by through holes 342a-d and/or partial holes 342e-f. In some cases, a pin (e.g., columnar or cylindrical conductive structure) may be connected to a trace by a hole partially formed in the trace and/or conductive structure on a substrate or in material used for the trace-pin connection (e.g., solder), as shown for pin 340g connected to trace 322g by insertion/placement in hole 344. Holes 342a-d and partial holes 342e-f may be made (e.g., defined and fabricated) by any suitable technique(s); example techniques include, but are not limited to, drilling (laser or mechanical, etc.), photolithographic techniques, and etching. While not shown, plating, solder or other conductive material(s) may be used for connections between conductive traces 312a-g, 322a-g and pins 340a-g. As shown for pin 340c, for cases where a pin is inserted through a through hole and extends through a conductive trace, the amount of exposed pin may be set or controlled to be a desired distance or length (d).

FIG. 4 is a diagram showing a top view of an alternate example pin-connection structure 400, in accordance with the present disclosure. Structure 400 can include two substrates 410, 411 that are formed with areas along their perimeters, respectively, 412a-b and 413a-b, that are configured for receiving pins 440a-b. Substrates 410, 411 can be pushed together (movement indicated by arrows) to receive pins 440a-b for forming a pin-coupled coil structure in accordance with embodiments of the present disclosure. Conductive trace material (not shown) may be located/disposed on substrate 410 and/or substrate 411 prior to or after pins 440a-b have been received (sandwiched) by substrates 410, 411. Structure 400 may be used with pin-coupled coil structures and pin-coupled transformer structures in embodiments of the present disclosure.

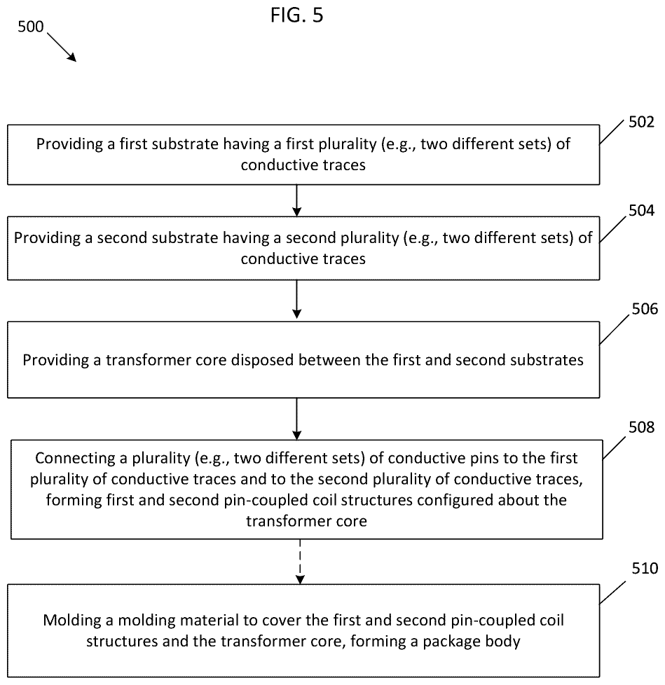

FIG. 5 is a box diagram showing an example method 500 of fabricating a pin-coupled transformer structure for an IC package, in accordance with the present disclosure. Method 500 can include providing a first substrate having a first plurality of conductive traces, as described at 502. The first substrate can include, but is not limited to, e.g., a PCB, molded lead frame, ceramic substrate, glass substrate, alumina substrate, etc. A second substrate can be provided having a second plurality of conductive traces, as described at 504. The second substrate can include, but is not limited to, e.g., a PCB, molded lead frame, ceramic substrate, glass substrate, alumina substrate, etc. A magnetic core can be provided, e.g., disposed between the first and second substrates, as described at 506. In some embodiments, an insulator material can be provided to the magnetic core to provide isolation. In some embodiments, the core may be insulated with an insulating tape on the core side(s)/surface(s) facing an adjacent substrate.

The first plurality of conductive traces can be connected to the second plurality of conductive traces with a plurality of conductive pins, forming first and second pin-coupled coil structures, as described at 508. The first and second pin-coupled coil structures can be used with the magnetic core for a transformer (transformer structure). A molding material can be molded to cover (overmold) the first and second coil structures and the transformer core, forming a package body, as described at 510. One or more IC die, e.g., two die, may be disposed in the package body and supported (directly or indirectly) by the first and/or second substrates, forming an IC package. In some examples, an IC package may include a gate driver that is galvanically isolated by the transformer structure, with the first and second coil structures forming primary and secondary coils for the transformer. The first and second pin-coupled coil structures and first and second IC die along with connecting conductive structure can form primary (input) and secondary (output) sides, respectively, of a transformer. In some embodiments and examples, the secondary side may be a high voltage side, e.g., with the transformer configured as a step up transformer.

In some embodiments, two PCBs having conductive traces can be connected by pins and used to make a (pin-coupled) transformer, which can then be added to a package (main) PCB. Similarly, two PCBs can be used to make a (pin-coupled) transformer, which can then be added to a molded leadframe. In either case, the package PCB or leadframe can be used to support the pin coupled transformer (including two PCBs, a core, and pins), and then two die can be placed on the molded lead frame or the package PCB board and the combined structures can be overmolded (covered with mold material during a molding process) to form an IC (semiconductor) package.

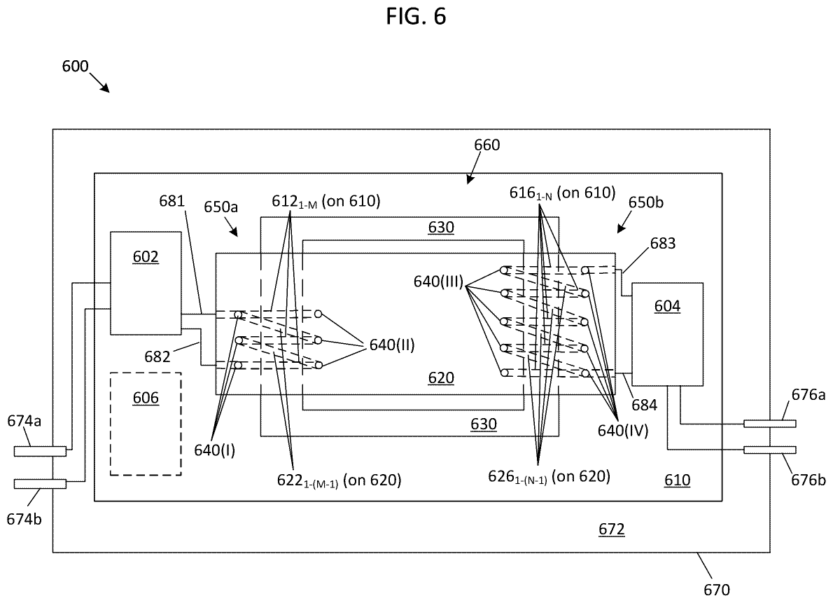

FIG. 6 is a diagram showing a side view of an example voltage-isolated IC package 600 with pin-coupled transformer structure, in accordance with the present disclosure. Package 600 can include one or more IC die disposed (directly or indirectly) on a first substrate 610. Two IC die (first and second die) 602, 604 are shown disposed on a common side of substrate 610 according to one embodiment. An alternate position for the second die is shown at 606 for another embodiment, representing placement on the opposite side of substrate 610. Second substrate 620 is also shown for package 600.

Each of the first and second substrates 610 and 620, includes a respective plurality of conductive traces, e.g., a plurality including sets 612_{1-M} and 616_{1-N} for substrate 610 and a plurality including sets 622_{1-(M-1)} and 626_{1-(N-1)} for substrate 620, as shown. The number of traces for the first and second substrates 610, 620, respectively, may be the same or different. A plurality of conductive structures such as columns or pins, e.g., including sets 640(I)-(IV), can connect the conductive traces of the substrates 610 and 620, forming first and second pin-coupled coil structures 650a-b, as described in further detail below.

As shown, pin-coupled coil structure 650a can include traces 612_{1-M} on substrate 610 connected to traces 622_{1-(M-1)} on substrate 620 by sets of pins (pin sets) 640(I) and 640(II). Similarly, pin-coupled coil structure 650b can includes trace 616_{1-N} on substrate 610 connected to traces 626_{1-(N-1)} on substrate 620 by sets of pins (pin sets) 640(III) and 640(IV). As shown, transformer core 630 is disposed between first and second substrates 610 and 620, forming pin-connected transformer structure (a.k.a., transformer) 660. Transformer core 630 can include soft ferromagnetic material. Pin-coupled coil structures 650a-b can operate as primary and secondary transformer coils of a transformer with transformer core 630. Pin-coupled coil structures 650a-b can also be connected to and provide galvanic separation of first and second die 602, 604. The first and second pin-coupled coil structures 650a-b and first and second IC die 604, 604 along with connecting conductive structure can form primary (input) and secondary (output) sides, respectively, of transformer 660. In some embodiments and examples, the secondary side may be a high voltage side, e.g., with the transformer 660 configured as a step up transformer.

As shown, package 600 can include a body 670 enclosing the above-noted components. Package body 670 may be made of or include any suitable material(s) 672, e.g., molding material, insulator, and/or potting material. Body 670 can have sets of leads or exposed conductive structures 674, 676, e.g., as indicated by 674a-b and 676a-b for the embodiments shown, configured to provide electrical connections to ICs of IC die 602, 604. Representative electrical connections 681-682 and 683-684 are shown between pin-coupled coil structure 650a-b and first and second IC die 602, 604. Other numbers of leads may be on the package body 670 such that 674 and 676 may have two leads as shown, which may be used when an electrical current is used to power and communicate outside the package 670. Other numbers of leads 674, 676, e.g., three, four, five, six, or more leads, may be on each electrical side (the low or high voltage side). The number of low voltage leads (e.g., of the primary or input side of transformer 660) and high voltage leads (e.g., of the secondary or output side of transformer 660) may be different on the package in some embodiments; in other embodiments, the number of low voltage leads and high voltage leads may be the same.

In some examples and/or embodiments, integrated circuits (Ics) in die 602, 604, and 606, or other conductive features of the primary and secondary sides of transformer structure 600, in or connected to the main body 670 can be fabricated or configured to have a desired separation distance (d) between certain parts or features, e.g., to meet internal creepage or external clearance requirements for a given pollution degree rating as defined by certain safety standards bodies such as the Underwriters Laboratories (UL) and the International Electrotechnical Commission (IEC). For example, a separation distance may be between closest (voltage) points of the respective circuits, e.g., the low-voltage (primary) side and high-voltage (secondary) side. For further example, such a separation distance may be the distance between any two voltage points between the primary and secondary sides, e.g., distance between conductive traces of the first substrate, i.e., 612_{1-M} and 616_{1-N}, or the distance between conductive traces of the second substrate, i.e., 622_{1-(M-1)} and 626_{1-(N-1)}, or a distance between die 602 and die 604, or a distance between exposed leads 674a-b and 676a-b in FIG. 6, may be or may be at least 1.2 mm, 1.4 mm, 1.5 mm, 3.0 mm, 4.0 mm, 5.5 mm, 7.2 mm, 8.0 mm, 10 mm, or 10+mm in respective examples. Such a distance between conductive portions or areas of die can include any insulation covering a conductor, e.g., such as plastic coating of a wire/lead. Other distances between conductive parts, components, and/or features of an IC package 600 may also be designed and implemented, e.g., to meet desired internal creepage, voltage breakdown, or external clearance requirements, e.g., between external leads 674a-b and 676a-b.

In some examples and embodiments, a dielectric material (e.g., gel) may be used for potting and/or protecting substrate (e.g., PCB) systems, assemblies, packages, e.g., such as IC package 600 modules, to protect die and/or interconnects from environment conditions and/or to provide dielectric insulation. In some examples, a dielectric material may include, but is not limited to, one or more of the following materials: DOWSIL™ EG-3810 Dielectric Gel (made available by The Dow Chemical Corporation, a.k.a., “Dow”, and DOWSIL™ EG-3896 Dielectric Gel (made available by Dow), which has the ability to provide isolation greater than 20 kV/mm. Other suitable gel materials may also or instead be used, e.g., to meet or facilitate meeting/achieving voltage isolation specifications required by a given package design. DOWSIL™ EG-3810 is designed for temperature ranges from −60° C. to 200° C. and DOWSIL™ EG-3896 Dielectric Gel −40° C. to +185° C.; both of which can be used to meet typical temperature ranges for automotive applications.

Accordingly, embodiments and/or examples of the inventive subject matter can afford various benefits relative to prior art techniques. For example, embodiments and examples of the present disclosure can enable or facilitate use of smaller size packages for a given power or voltage rating. Embodiments and examples of the present disclosure can enable or facilitate lower costs and higher scalability for manufacturing of IC packages/modules having voltage-isolated IC die and transformers.

Various embodiments of the concepts, systems, devices, structures, and techniques sought to be protected are described above with reference to the related drawings. Alternative embodiments can be devised without departing from the scope of the concepts, systems, devices, structures, and techniques described. For example, pin-coupled coil structures (e.g., primary and secondary transformer coils) may each have a whole number or fractional number of turns (loops about a related core or structure intended to receive a core), e.g., 1.5, 2.5, 1.75, 1.8, 2.25, etc.

It is noted that various connections and positional relationships (e.g., over, below, adjacent, etc.) may be used to describe elements and components in the description and drawings. These connections and/or positional relationships, unless specified otherwise, can be direct or indirect, and the described concepts, systems, devices, structures, and techniques are not intended to be limiting in this respect. Accordingly, a coupling of entities can refer to either a direct or an indirect coupling, and a positional relationship between entities can be a direct or indirect positional relationship.

As an example of an indirect positional relationship, positioning element “A” over element “B” can include situations in which one or more intermediate elements (e.g., element “C”) is between elements “A” and elements “B” as long as the relevant characteristics and functionalities of elements “A” and “B” are not substantially changed by the intermediate element(s).

Also, the following definitions and abbreviations are to be used for the interpretation of the claims and the specification. The terms “comprise,” “comprises,” “comprising,” “include,” “includes,” “including,” “has,” “having,” “contains” or “containing,” or any other variation are intended to cover a non-exclusive inclusion. For example, an apparatus, a method, a composition, a mixture, or an article, which includes a list of elements is not necessarily limited to only those elements but can include other elements not expressly listed or inherent to such apparatus, method, composition, mixture, or article.

Additionally, the term “exemplary” means “serving as an example, instance, or illustration.” Any embodiment or design described as “exemplary” is not necessarily to be construed as preferred or advantageous over other embodiments or designs. The terms “one or more” and “at least one” indicate any integer number greater than or equal to one, i.e., one, two, three, four, etc.; however, those terms may refer to fractional numbers where context admits, e.g., a number of loops in a transformer coil (e.g., pin-coupled coil structure) may be a fractional value, e.g., 2.75, 3.5, 4.25, etc. The term “plurality” indicates any integer number greater than one. The term “connection” can include an indirect “connection” and a direct “connection.”

References in the specification to “embodiments,” “one embodiment, “an embodiment,” “an example embodiment,” “an example,” “an instance,” “an aspect,” etc., indicate that the embodiment described can include a particular feature, structure, or characteristic, but every embodiment may or may not include the particular feature, structure, or characteristic. Moreover, such phrases do not necessarily refer to the same embodiment. Further, when a particular feature, structure, or characteristic is described in connection with an embodiment, it may affect such feature, structure, or characteristic in other embodiments whether explicitly described or not.

Relative or positional terms including, but not limited to, the terms “upper,” “lower,” “right,” “left,” “vertical,” “horizontal, “top,” “bottom,” and derivatives of those terms relate to the described structures and methods as oriented in the drawing figures. The terms “overlying,” “atop,” “on top, “positioned on” or “positioned atop” mean that a first element, such as a first structure, is present on a second element, such as a second structure, where intervening elements such as an interface structure can be present between the first element and the second element. The term “direct contact” means that a first element, such as a first structure, and a second element, such as a second structure, are connected without any intermediary elements.

Use of ordinal terms such as “first,” “second,” “third,” etc., in the claims to modify a claim element does not by itself connote any priority, precedence, or order of one claim element over another, or a temporal order in which acts of a method are performed but are used merely as labels to distinguish one claim element having a certain name from another element having a same name (but for use of the ordinal term) to distinguish the claim elements.

The terms “approximately” and “about” may be used to mean within ±20% of a target (or nominal) value in some embodiments, within plus or minus (±) 10% of a target value in some embodiments, within ±5% of a target value in some embodiments, and yet within ±2% of a target value in some embodiments. The terms “approximately” and “about” may include the target value. The term “substantially equal” may be used to refer to values that are within ±20% of one another in some embodiments, within ±10% of one another in some embodiments, within ±5% of one another in some embodiments, and yet within ±2% of one another in some embodiments.

The term “substantially” may be used to refer to values that are within ±20% of a comparative measure in some embodiments, within ±10% in some embodiments, within ±5% in some embodiments, and yet within ±2% in some embodiments. For example, a first direction that is “substantially” perpendicular to a second direction may refer to a first direction that is within ±20% of making a 90° angle with the second direction in some embodiments, within ±10% of making a 90° angle with the second direction in some embodiments, within ±5% of making a 90° angle with the second direction in some embodiments, and yet within ±2% of making a 90° angle with the second direction in some embodiments.

The disclosed subject matter is not limited in its application to the details of construction and to the arrangements of the components set forth in the following description or illustrated in the drawings. The disclosed subject matter is capable of other embodiments and of being practiced and carried out in various ways.

Also, the phraseology and terminology used in this patent are for the purpose of description and should not be regarded as limiting. As such, the conception upon which this disclosure is based may readily be utilized as a basis for the designing of other structures, methods, and systems for carrying out the several purposes of the disclosed subject matter. Therefore, the claims should be regarded as including such equivalent constructions as far as they do not depart from the spirit and scope of the disclosed subject matter.

Although the disclosed subject matter has been described and illustrated in the foregoing exemplary embodiments, the present disclosure has been made only by way of example. Thus, numerous changes in the details of implementation of the disclosed subject matter may be made without departing from the spirit and scope of the disclosed subject matter.

Accordingly, the scope of this patent should not be limited to the described implementations but rather should be limited only by the spirit and scope of the following claims.

All publications and references cited in this patent are expressly incorporated by reference in their entirety.

What is claimed is:

1. A pin-coupled transformer structure comprising:
a first substrate having a first plurality of conductive traces;
a second substrate having a second plurality of conductive traces;
a soft ferromagnetic core configured as a closed loop and disposed between the first and second substrates; and
a plurality of conductive pins disposed between and connecting the first plurality of conductive traces to the second plurality of conductive traces;
wherein the first and second pluralities of conductive traces and the plurality of conductive pins comprise first and second pin-coupled coil structures and are configured about the soft ferromagnetic core as first and second transformer coils.

2. The transformer structure of claim 1, wherein the first and second pin-coupled coil structures are galvanically separated.

3. The transformer structure of claim 1, wherein the first and/or second substrate comprises a printed circuit board (PCB).

4. The transformer structure of claim 1, wherein the first and/or second substrate comprises a lead frame.

5. The transformer structure of claim 4, wherein the first and/or second substrate comprises a molded lead frame.

6. The transformer structure of claim 1, wherein the first and/or second substrate comprises a glass substrate including a plurality of thin glass layers.

7. The transformer structure of claim 1, wherein the first and/or second substrate comprises a ceramic substrate.

8. The transformer structure of claim 7, wherein the ceramic substrate comprises high-temperature cofired ceramic (HTCC).

9. The transformer structure of claim 7, wherein the ceramic substrate comprises low-temperature cofired ceramic (LTCC).

10. The transformer structure of claim 1, further comprising an IC die connected to the first pin-coupled coil structure.

11. The transformer structure of claim 10, where the IC die comprises an integrated circuit.

12. The transformer structure of claim 1, further comprising an IC die connected to second pin-coupled coil structure.

13. The transformer structure of claim 12, where the IC die comprises an integrated circuit.

14. The transformer structure of claim 13, wherein the integrated circuit comprises a gate driver circuit.

15. The transformer structure of claim 1, wherein the first pin-coupled coil structure comprises a primary side of the transformer structure.

16. The transformer structure of claim 1, wherein the second pin-coupled coil structure comprises a secondary side of the transformer structure.

17. The transformer structure of claim 1, further comprising a dielectric material disposed between the first and second pin-coupled coil structures.

18. The transformer structure of claim 1, further comprising a dielectric tape material disposed about the soft ferromagnetic core to facilitate isolation between the soft ferromagnetic core and the first and second substrates.

19. The transformer structure of claim 1, further comprising a molding material configured to cover the first and second pin-coupled coil structures and soft ferromagnetic core, and wherein the molding material is configured as a package body.

20. A method of making a pin-coupled transformer structure, the method comprising:
providing a first substrate having a first plurality of conductive traces;
providing a second substrate having a second plurality of conductive traces;
providing a soft ferromagnetic core configured as a closed loop and disposed between the first and second substrates; and
connecting a plurality of conductive pins to the first plurality of conductive traces and to the second plurality of conductive traces;
wherein the first and second pluralities of conductive traces and the plurality of conductive pins comprise first and second pin-coupled coil structures and are configured about the soft ferromagnetic core as first and second transformer coils.

21. The method of claim 20, wherein the first and second pin-coupled coil structures are galvanically separated.

22. The method of claim 20, wherein the first and/or second substrate comprises a printed circuit board (PCB).

23. The method of claim 20, wherein the first and/or second substrate comprises a molded lead frame.

24. The method of claim 20, wherein the first and/or second substrate comprises a glass substrate including a plurality of thin glass layers.

25. The method of claim 20, wherein the first and/or second substrate comprises a ceramic substrate.

26. The method of claim 25, wherein the ceramic substrate comprises high-temperature cofired ceramic (HTCC).

27. The method of claim 25, wherein the ceramic substrate comprises low-temperature cofired ceramic (LTCC).

28. The method of claim 20, further comprising providing a semiconductor die disposed on the first and/or second substrate.

29. The method of claim 28, where the semiconductor die comprises an integrated circuit.

30. The method of claim 29, wherein the semiconductor die is disposed on a high-voltage side of the transformer structure and wherein the integrated circuit comprises a gate driver circuit.

31. The method of claim 20, further comprising providing a molding material configured to cover the first and second pin-coupled coil structures and soft ferromagnetic core, wherein the molding material is configured as a package body.
